(19) United States
(12) Patent Application Publication
(10) Pub. No.: US 2021/0210615 A1
(43) Pub. Date: Jul. 8, 2021

(54) TRANSISTOR STRUCTURE AND METHOD FOR MANUFACTURING THE SAME

(71) Applicant: Nexchip Semiconductor Co., LTD, Hefei (CN)

(72) Inventors: Jing ZHANG, Hefei (CN); Qizhun JIN, Hefei (CN)

(73) Assignee: Nexchip Semiconductor Co., LTD, Hefei (CN)

(21) Appl. No.: 16/851,086

(22) Filed: Apr. 16, 2020

(30) Foreign Application Priority Data
Jan. 2, 2020 (CN) 2020100026967
Mar. 4, 2020 (CN) 2020101442673
Mar. 4, 2020 (CN) 2020202576647

(51) Int. Cl. H01L 29/66; H01L 29/78; H01L 21/02; H01L 21/311; H01L 21/265

(52) U.S. Cl. CPC H01L 29/6656; H01L 29/7833; H01L 21/02164; H01L 29/6653; H01L 21/31111; H01L 21/26513; H01L 29/66492; H01L 21/0217

(57) ABSTRACT

The present disclosure discloses a transistor structure and a method for manufacturing the same. The method includes: preparing a substrate, a plurality of gate structures are disposed on the substrate; forming a first spacer structure on both sidewalls of each gate structure; and forming a film layer, the film layer covers the substrate, the plurality of gate structures, the second spacer structure and the step structure. The present disclosure solves the problem that defects caused by growth speed differences of films at spacers of the gate structures and the substrate, such as deep pits or holes, occur in a film deposition process, thereby avoiding electricity leakage of a subsequent contact pipeline and failure of a device, thus ensuring the quality of the transistor product.

### CROSS REFERENCES TO RELATED APPLICATIONS

This application claims the benefit of priority to Chinese Patent Application No. CN 2020100026967, filed with CNIPO on Jan. 2, 2020, claims the benefit of priority to Chinese Patent Application No. CN 2020202576647, filed with CNIPO on Mar. 4, 2020, and claims the benefit of priority to Chinese Patent Application No. CN 2020101442673, filed with CNIPO on Mar. 4, 2020, the contents of which are incorporated herein by reference in their entireties.

### TECHNICAL FILED

The present disclosure relates to the technical field of semiconductor, and in particular, to a transistor and a method for manufacturing the same.

### BACKGROUND

If the ion implantation region of the source region and the drain region is too close to the gate region, the short channel effect will be caused. In order to avoid the short channel effect, and to protect the sidewalls of the gate region, source region and drain region should be isolated from the gate region of memory cells. Spacers are generally manufactured on the sidewalls of the gate region. For some memory cells, a depth-to-width ratio of a region between the adjacent spacers has stringent requirements for film deposition capability. Even a high-density plasma chemical vapor deposition (HDP) process has good hole filling capability, large deep pits cannot be covered. Due to growth speed differences of films at the spacers and a substrate, depression or pinch-off is easy to be caused in the middle of the deep pits. When the depression or pinch-off is serious, shoulders of the two spacers may form gaps or holes, causing electricity leakage of a subsequent contact pipeline and failure of a device, thereby influencing the quality of a memory product. In addition, an important effect of the spacers is to protect regions such as a lightly doped drain (LDD), a source/drain extension (SDE) and Halo during subsequent deeper ion implantation, so that the short channel effect is effectively inhibited, and the effect of a high resistance value of the source/drain caused by a shallow junction is reduced. Therefore, a manufacturing process is required to strictly control the source/drain regions and sizes, which cause that existing spacer structure cannot be directly thinned.

### SUMMARY

The present disclosure provides a transistor structure and a method for manufacturing the same, and solves the problem that deep pits or holes caused by growth speed differences of films at spacers of gate structures and a substrate occurs in a film deposition process, so that electricity leakage of a subsequent contact transistor and failure of a device are avoided, thus ensuring the quality of a transistor product.

The present disclosure provides a method for manufacturing a transistor structure, at least comprising the following operations: preparing a substrate, a plurality of gate structures are disposed on the substrate, and a preset spacing distance is formed between the adjacent gate structures; forming a first spacer structure on both sidewalls of each gate structure, the first spacer structure comprises a silicon oxide layer and a silicon nitride layer, and removing the silicon nitride layer disposed on the substrate and between the adjacent first spacer structures; performing ion implantation on the substrate; removing the silicon oxide layer disposed on the substrate between the adjacent first spacer structures to expose the substrate between the adjacent first spacer structures; removing the silicon nitride layer in the first spacer structure to form second spacer structure and the step structure, the second spacer structure are formed on both sidewalls of each gate structure, and the step structure is formed between the second spacer structure and the substrate; and forming a film layer, where the film layer covers the substrate, the plurality of gate structures, the second spacer structure and the step structure.

In one embodiment of the present disclosure, the preset spacing distance is 80 nm to 110 nm.

In one embodiment of the present disclosure, the second spacer structure is a silicon oxide layer.

In one embodiment of the present disclosure, the step structure is a silicon oxide layer.

In one embodiment of the present disclosure, a thickness of the second spacer structure is 6 nm to 10 nm.

In one embodiment of the present disclosure, a thickness of the step structure is 6 nm to 10 nm.

In one embodiment of the present disclosure, method further comprises forming a gate oxide layer on the substrate.

In one embodiment of the present disclosure, the silicon nitride layer on the substrate is removed by a selective etching solution.

The present disclosure further provides a transistor structure, comprising: a substrate; a plurality of gate structures, disposed on the substrate, a preset spacing distance is formed between the adjacent gate structures; a second spacer structure, formed on both sidewalls of each gate structure; a step structure, disposed at a junction of the second spacer structures and the substrate; and a film layer, disposed on the substrate, and covering the substrate, the plurality of gate structures, the second spacer structure and the step structure.

In one embodiment of the present disclosure, the transistor structure further comprises a gate oxide layer. The gate oxide layer is disposed on the substrate and between the substrate and the plurality of gate structures.

By increasing the space between spacers of the adjacent gate structures, the film deposition is more uniform, the interface in the deposition process is flatter, and the problem that film deposition in a space is easy to cause gaps and holes is effectively avoided. Increasing the space between the spacers of the adjacent gate structures can effectively avoid depression and pinch-off of a film crystal structure between the spacers and the substrate caused by the growth speed differences of the films at the spacers and the films near the substrate, thereby avoiding the electricity leakage and failure of the device in a later period. The present application can ensure that the coverage of the gate structures and the substrate through the spacer structure and the step structure, and ensure that the subsequent ion implantation process does not affect a manufacturing process region in an early period.

Certainly, it is not necessary for any one product implementing the present disclosure to achieve all of the above-mentioned advantages at the same time.

### BRIEF DESCRIPTION OF THE DRAWINGS

FIG. 1 is a flow diagram of a method for manufacturing a transistor structure according to the present disclosure.

FIG. 2 is a schematic diagram of cross-sectional view of operation S1 in FIG. 1.

FIG. 3 is a schematic diagram of cross-sectional view of operations S2 and S3 in FIG. 1.

FIG. 4-FIG. 5 are schematic diagram of cross-sectional views of operation S4 in FIG. 1.

FIG. 6 is a schematic diagram of cross-sectional view of operation S5 in FIG. 1.

FIG. 7 is a schematic diagram of cross-sectional view of operation S6 in FIG. 1.

### DETAILED DESCRIPTION OF THE PREFERRED EMBODIMENTS

The following clearly and completely describes the technical solutions in the embodiments of the present disclosure with reference to the accompanying drawings in the embodiments of the present disclosure. Obviously, the described embodiments are only some embodiments instead of all embodiments of the present disclosure. All other embodiments obtained by a person of ordinary skill in the art based on the embodiments of the present disclosure without creative efforts shall fall within the protection scope of the present disclosure.

It should be noted that the drawings provided in the following embodiments only exemplify the basic idea of the present disclosure. Therefore, only the components related to the present disclosure are shown in the drawings, and are not drawn according to the quantity, shape, and size of the components during actual implementation. During actual implementation, the type, quantity, and proportion of the components may be changed, and the layout of the components may be more complicated.

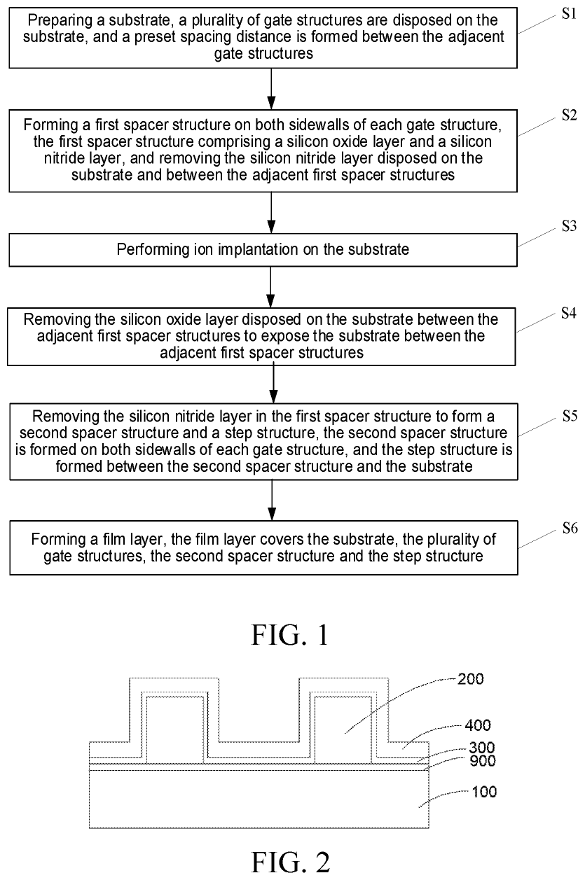

Referring to FIG. 1, the present disclosure provides a method for manufacturing a transistor structure, at least comprising the following operations:

S1: preparing a substrate 100. A plurality of gate structure 200 is disposed on the substrate 100. The adjacent gate structures 200 have a preset spacing distance therebetween.

S2: forming a first spacer structure 500 on both sidewalls of each gate structure 200. The first spacer structure 500 includes a silicon oxide layer 300 and a silicon nitride layer 400. The silicon nitride layer 400 disposed on the substrate 100 and between the adjacent first spacer structures 500 is removed.

S3: performing ion implantation on the substrate 100.

S4: removing the silicon oxide layer 300 disposed on the substrate 100 and between the adjacent first spacer structures 500, and exposing the substrate 100 between the adjacent first spacer structures 500.

S5: removing the silicon nitride layer 400 in the first spacer structures 500 to form the second spacer structure 600 and the step structure 700. The second spacer structure 600 is formed on both sidewalls of each gate structure 200. The step structure 700 is formed between the second spacer structure 600 and the substrate 100.

S6: forming a film layer 800 on the substrate 100. The film layer 800 covers the substrate 100, the plurality of gate structures 200, the second spacer structures 600 and the step structures 700.

The method for manufacturing a memory according to the present disclosure is illustrated hereafter in detail with reference to FIGS. 2 to 7.

Referring to FIG. 2, in operation S1, the substrate 100 is prepared. The substrate 100 may include a memory cell region and a peripheral circuit region. The present embodiment takes the memory cell region as an example, but it should be understood that method according to the present disclosure is also applicable to the peripheral circuit region. The plurality of gate structures 200 is disposed on the memory cell region of the substrate 100. A dielectric layer covering the gate structure 200 is disposed on the gate structures 200. The dielectric layer includes the silicon oxide layer 300 and the silicon nitride layer 400 sequentially formed on the surfaces of the gate structures 200.

Referring to FIG. 2, in some other embodiments, in operation S1, a gate oxide layer 900 may be formed on the substrate 100. A material of the gate oxide layer 900 may be, for example, silicon oxide. In the present embodiment, the gate oxide layer 900 of the silicon oxide material may be formed by, for example, furnace tube oxidization, rapid thermal annealing oxidization, in situ water vapor oxidation or other thermal oxidization methods.

Referring to FIG. 2, in operation S1, a material of the substrate 100 may be silicon, germanium, silicon-germanium, silicon carbide, or the like, or may be silicon-on-insulator (SOI) or germanium-on-insulator (GOD, or may be other materials, for example, group III and V compounds such as gallium arsenide. The substrate 100 may be implanted with certain doping particles according to design requirements, so as to change electrical parameters. The substrate 100 may be a p type or n type silicon substrate 100.

Referring to FIG. 2, in operation S1, in a manufacturing process of the memory such as a flash memory, manufacturing processes of a memory cell, a logic transistor and a high-voltage transistor are generally performed on the same substrate 100 at the same time. The memory cell and the high-voltage transistor are disposed in the high-voltage regions to form the flash memory. It should be understood by those skilled in the art that the method according to the present disclosure may also be used to manufacture logic circuits on the same substrate 100.

Referring to FIG. 2, in operation S1, the gate structure 200 according to the present embodiment may be a stacked gate structure. The stacked gate structure 200 includes a gate oxide layer 900, a floating gate and a control gate which are sequentially stacked on the surface of the substrate 100. The control gate and the floating gate are generally made of polycrystalline silicon, and can perform data writing and erasing through a tunneling effect. The preset spacing distance between the adjacent gate structures 200 range from 80 nm to 110 nm.

Referring to FIG. 2, in operation S1, the gate structures 200 according to the present embodiment may be formed by chemical vapor deposition, photoetching, or the like. Specifically, the gate structures 200 may be formed by methods known by those skilled in the art, and those methods will not be described in detail. Therefore, in this operation, it may be regarded that the following process operations, but not limited to those operations, have been completed on the substrate 100: well implantation performed in the memory cell region, such as deep N well implantation; isolation channels formed in the memory cell region, such as shallow groove isolation structures. Additionally, only two gate structures 200 are shown in FIG. 2, but it should be understood by those skilled in the art that in order to clearly illustrate key points of the present application, only parts of the devices and structures in the memory cell regions of the memory are shown in a way of schematic diagram. It is not intended that the memory process only include those parts, and well-known memory structures and process operations may also be included herein.

Referring to FIG. 2, in operation S1, after forming the gate structures 200, an oxide-nitride (ON) dielectric layer may be formed on the surfaces of the gate structures 200. The ON dielectric layer covers the gate structures 200. In the present embodiment, the ON dielectric layer includes the silicon oxide layer 300 and the silicon nitride layer 400 sequentially formed on the surface of the gate structure 200. The silicon oxide layer 300, for example, may be silicon oxynitride or silicon dioxide. Specifically, the silicon oxide layer 300 covers the surfaces of the gate structures 200, including sidewalls and the exposed surface of the substrate 100, and the silicon nitride layer 400 is stacked on the surface of the silicon oxide layer 300.

Referring to FIG. 2, in operation S1, the ON dielectric layer may be formed by chemical vapor deposition. In the present embodiment, the thickness of each layer of the ON dielectric layer may be set by using existing processes, and may be a conventional thickness.

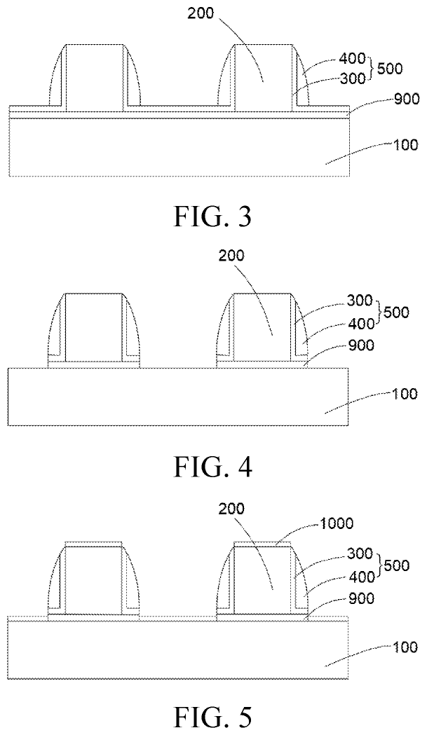

Referring to FIG. 3, in operation S2, the first spacer structure 500 is manufactured. The first spacer structure 500 covers the sidewall of the gate structure 200. The first spacer structure 500 includes the silicon oxide layer 300 and the silicon nitride layer 400.

Referring to FIG. 3, in operation S2, specifically, the ON dielectric layer is etched downwards in the direction perpendicular to the substrate 100 by a dry etching process, so that the silicon nitride layer 400 formed on top of the gate structure 200 and formed on the substrate 100 between the adjacent first spacer structures 500 are removed. The top surface of the gate structures 200 and silicon oxide layer 300 on the substrate 100 between the adjacent first spacer structures 500 are exposed.

Referring to FIG. 3, in operation S2, for dry etching, the etching gas may be one or more of a group formed by HBr, HeBr, Cl₂, O₂, N₂, NF₃, Ar or HeO₂ and CF₄.

Referring to FIG. 3, in operation S3, a source and drain ion implantation process is performed on the substrate 100 to form a source region and a drain region. Methods for performing source and drain implantation on the substrate 100 to form the source region and the drain region may be well-known methods. In a source and drain implantation process, in order to avoid effect on a non-implantation region on the substrate 100, the non-implantation region may be shielded by a photoresist.

Referring to FIG. 3, in operation S3, in the present embodiment, the first spacer structure 500 may prevent the short channel effect caused by too close of the source region and the drain region from the gate structure 200, and protect the sidewall of the gate structure 200.

Referring to FIG. 4, in operation S4, the silicon oxide layer 300 disposed on the substrate 100 between the adjacent first spacer structures 500 is removed to expose the substrate 100. In some embodiments, the silicon oxide layer 300 and the gate oxide layer disposed on the substrate 100 between the adjacent first spacer structures 500 are removed to expose the substrate 100 in this position. Specifically, the oxide silicon layer 300 may be removed by the wet etching process. For example, the silicon oxide layer 300 on the substrate 100 is removed by HF solution. In other embodiments, the oxide silicon layer 300 may be removed by dry etching process, and the dry etching has a high etching selection ratio for silicon oxide and silicon nitride, for example, greater than 10.

Referring to FIG. 5, in operation S4, Co or Ni is deposited on the top surface of the gate structure 200 and the exposed substrate 100 to form metal silicide layer 1000. The metal silicide layer 1000 may reduce contact resistance of the contact window at the top of the gate and the substrate 100.

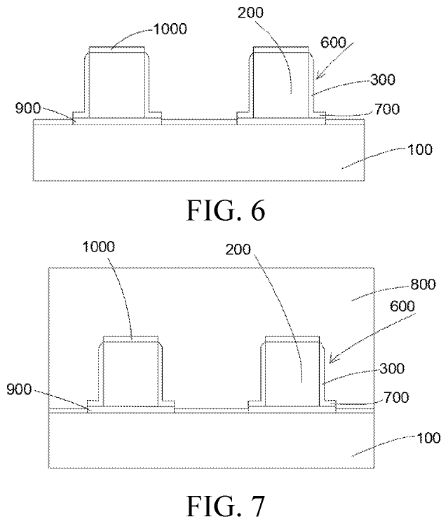

As shown in FIG. 6, in operation S5, the rest silicon nitride layer 400 is removed. A second spacer structure 600 is formed on the both sidewalls of each gate structure 200. The step structure 700 is formed between the second spacer structure 600 and the substrate 100. The thickness of the second spacer structure 600 is, for example, 6 nm to 10 nm. The thickness of the step structure 700 is, for example, 6 nm to 10 nm. The length of the step structure 700 may be adjusted according to specific products. Specifically, the silicon nitride layer 400 may be removed by a selective corrosion solution in the wet etching process. In the present embodiment, for example, a phosphoric acid solution may be used. The phosphoric acid solution has a selective corrosion effect on the silicon nitride layer 400 and the silicon oxide layer 300. The silicon nitride layer 400 is corroded, while silicon oxide layer 300 is not corroded. Therefore, with phosphoric acid used as an etching solution, the silicon nitride layer 400 may be completely removed while the silicon oxide layer 300 is retained. After the silicon nitride layer 400 is removed, the space for depositing film in a later period is increased, the depression occurring in the surface of deposited film is reduced, the flatness of the surface of deposited film is effectively ensured, and gaps and holes are prevented from being formed between the adjacent gate structures 200. The regions formed in an early period, such as the lightly doped region in drain terminal and the source/drain expansion region, will not be affected by deeper ion implantation in the later period due to protection by the silicon oxide layer 300, thus effectively improving the quality of a final product.

Referring to FIG. 7 together, in operation S6, a dielectric film layer 800 is deposited on the substrate 100, and conventional subsequent processes are performed to obtain the memory according to the present disclosure.

Referring to FIG. 7, in operation S6, the dielectric film layer 800 may be an interlayer dielectric (ILD). The material of dielectric film layer 800 may be, for example, SiO2 or borosilicate glass (PSG). A dielectric film may be deposited by the chemical vapor deposition method, such as APCVD, LPCVD or PECVD.

Referring to FIG. 1 to FIG. 6, based on the above, by increasing the space between the adjacent second spacer structures 600, the depression on the film deposition interface is reduced, so that the flatness of the interface in the film layer deposition process in the later period is effectively ensured. The defects such as gaps and holes formed between the adjacent gate structures 200 are avoided. In the memory structure with a great depth-to-width ratio, this effect is especially obvious. The region between the adjacent second spacer structures 600 is increased while the region covered by the substrate 100 is not reduced, so that the manufacturing processes in the later period will not affect the manufacturing processes in the early period.

Referring to FIG. 6, the present disclosure further provides a transistor structure. The transistor structure includes a substrate 100, a plurality of gate structures 200, a second spacer structure 600, a step structure 700 and a film layer 800.

Referring to FIG. 6, the substrate 100 may include a memory cell region and a peripheral circuit region. The present embodiment takes the memory cell region as an example, but it should be understood that method according to the present disclosure is also applicable to the peripheral circuit region. The plurality of gate structures 200 is disposed on the memory cell region of the substrate 100. A dielectric layer covering the gate structure 200 is disposed on the gate structures 200. The dielectric layer includes the silicon oxide layer 300 and the silicon nitride layer 400 sequentially formed on the surfaces of the gate structures 200.

Referring to FIG. 6, in some other embodiments, a gate oxide layer 900 may be formed between the substrate 100 and the plurality of gate structures 200. The gate oxide layer 900 serves as an insulation dielectric between the gate structure 200 and the substrate 100. In the present embodiment, the gate oxide layer may be, for example, made of a silicon dioxide.

Referring to FIG. 6, the material of the substrate 100 may be silicon, germanium, silicon-germanium, silicon carbide, or the like, or may be silicon-on-insulator (SOI) or germanium-on-insulator (GOI), or may be other materials, for example, group III and V compounds such as gallium arsenide. The substrate 100 may be implanted with certain doping particles according to design requirements so as to change electrical parameters. The substrate 100 may be a p type or n type silicon substrate 100.

Referring to FIG. 6, in a manufacturing process of a memory such as a flash memory, manufacturing processes of a memory cell, a logic transistor and a high-voltage transistor are generally performed on the same substrate 100 at the same time. The memory cell and the high-voltage transistor are disposed in the high-voltage regions and to form the flash memory. It should be understood by those skilled in the art that the method according to the present disclosure may also be used to manufacture logic circuits on the same substrate 100.

Referring to FIG. 6, the gate structure 200 according to the present embodiment may be a stacked gate structure. The stacked gate structure 200 includes a gate oxide layer 900, a floating gate and a control gate which are sequentially stacked on the surface of the substrate 100. A tunneling oxide layer is formed between the floating gate and the control gate. The control gate and the floating gate are generally made of polycrystalline silicon, and can perform data writing and erasing through a tunneling effect.

Referring to FIG. 6, a second spacer structure 600 is formed on both sidewalls of each gate structure 200. The step structure 700 is formed between the second spacer structure 600 and the substrate 100. The second spacer structure 600 and the step structure 700 are silicon oxide layers 300. The thickness of the second spacer structure 600 is, for example, 6 nm to 10 nm. The thickness of the step structure 700 is, for example, 6 nm to 10 nm.

Referring to FIG. 6, the thickness of the second spacer structure 600 formed after source and drain ion implantation is thinner than that of the existing spacer between the gate structures 200, so that the space between the adjacent gate structures 200 is increased, thereby effectively ensuring the flatness of an interface in a deposition process of the film layer 800 in a later period and preventing defects such as gaps and holes formed between the adjacent gate structures 200. In the flash memory with a special depth-to-width ratio, this effect is especially obvious. The step structure 700 increases the region between the adjacent second spacer structures 600, and ensures the coverage region of the substrate 100, so that the manufacturing processes in the later period will not affect the manufacturing processes in an early period.

The exemplary embodiments of the present disclosure disclosed above are only used to help explain the present disclosure. The exemplary embodiments do not describe all the details, and are not intended to limit the present disclosure to the specific implementations described. Obviously, many modifications and changes may be made according to the content of this specification. These embodiments are selected and described in this specification for better explaining the principles and practical applications of the present disclosure, so that those skilled in the art can better understand and use the present disclosure. The present disclosure is limited only by the claims and full scope and equivalents thereof.

What is claimed is:

1. A method for manufacturing a transistor structure, at least comprising:
preparing a substrate, wherein a plurality of gate structures are disposed on the substrate, and a preset spacing distance is formed between the adjacent gate structures;
forming a first spacer structure on both sidewalls of each gate structure, the first spacer structure comprising a silicon oxide layer and a silicon nitride layer, and removing the silicon nitride layer disposed on the substrate and between the adjacent first spacer structures;
performing ion implantation on the substrate;
removing the silicon oxide layer disposed on the substrate between the adjacent first spacer structures to expose the substrate between the adjacent first spacer structures;
removing the silicon nitride layer in the first spacer structure to form a second spacer structure and a step structure, wherein the second spacer structure is formed on both sidewalls of each gate structure, and the step structure is formed between the second spacer structure and the substrate; and
forming a film layer, wherein the film layer covers the substrate, the plurality of gate structures, the second spacer structure and the step structure.

2. The method for manufacturing a transistor structure according to claim 1, wherein the preset spacing distance is 80 nm to 110 nm.

3. The method for manufacturing a transistor structure according to claim 1, wherein the second spacer structure is a silicon oxide layer.

4. The method for manufacturing a transistor structure according to claim 1, wherein the step structure is a silicon oxide layer.

5. The method for manufacturing a transistor structure according to claim 1, wherein a thickness of the second spacer structure is 6 nm to 10 nm.

6. The method for manufacturing a transistor structure according to claim 1, wherein a thickness of the step structure is 6 nm to 10 nm.

7. The method for manufacturing a transistor structure according to claim 1, further comprising forming a gate oxide layer on the substrate.

8. The method for manufacturing a transistor structure according to claim 1, wherein the silicon nitride layer on the substrate is removed by a selective etching solution.

9. A transistor structure, comprising:
a substrate;
a plurality of gate structures, disposed on the substrate, wherein a preset spacing distance is formed between the adjacent gate structures;
a second spacer structure, disposed on both sidewalls of each gate structure;
a step structure, formed at a junction of the second spacer structure and the substrate; and
a film layer, disposed on the substrate, and covering the substrate, the plurality of gate structures, the second spacer structure and the step structure.

10. The transistor structure according to claim 9, further comprising a gate oxide layer, wherein the gate oxide layer is disposed on the substrate and between the substrate and the plurality of gate structures.
